(19) United States
(12) Patent Application Publication
(10) Pub. No.: US 2025/0311368 A1
(43) Pub. Date: Oct. 2, 2025

(54) POWER DEVICE AND MANUFACTURING METHOD THEREOF

(71) Applicant: HUNAN SAN’AN SEMICONDUCTOR CO.,LTD., Changsha (CN)

(72) Inventors: Han XU, Changsha (CN); Cheng LIU, Changsha (CN); NIEN TZE YEH, Changsha (CN)

(21) Appl. No.: 19/026,420

(22) Filed: Jan. 17, 2025

(30) Foreign Application Priority Data
Mar. 29, 2024 (CN) 202410381635.4

(51) Int. Cl. H10D 64/27; H10D 30/01; H10D 30/47; H10D 30/63; H10D 62/00; H10D 62/17; H10D 64/01

(52) U.S. Cl. CPC H10D 64/518; H10D 30/47; H10D 30/637; H10D 62/235; H10D 62/343; H10D 30/027; H10D 62/01; H10D 64/01

(57) ABSTRACT

A power device and a manufacturing method thereof are provided. The power device includes a compound semiconductor composite layer, a P-type gate layer, a source, a drain, and a gate electrode layer. The P-type gate layer, the source and the drain are all disposed on the compound semiconductor composite layer. The gate electrode layer is disposed on the P-type gate layer. A sidewall of the P-type gate layer facing towards the drain includes a P-type gate slope, and the P-type gate slope is inclined towards the source relative to a surface of the compound semiconductor composite layer.

### TECHNICAL FIELD

The present disclosure relates to the technical field of semiconductors, and particularly to a power device and a manufacturing method of a power device.

### BACKGROUND

In the field of power application, people are more accustomed to using an enhancement-mode device (which is also referred to as a normally closed device, the normally closed device is in a closed state when a control voltage is zero) based the reasons as follows: a whole circuit of a depletion-mode device may be short-circuited and a whole system may be burned when the depletion-mode device (which is also referred to as a normally on device, the normally on device is in an open state when a control voltage is zero) fails. In addition, the depletion-mode device usually needs a negative pressure to turn off the depletion-mode device, which increases the complexity of circuit design, which is not conducive to optimizing a system volume and reducing a system cost. Moreover, for a gallium nitride device, a heterostructure of AlGaN/GaN makes a large number of electrons naturally exist in a channel, which makes that all of the early gallium nitride devices are depletion devices. Therefore, how to prepare an enhancement-mode gate structure with higher performance and higher reliability has always been a hot topic in academia and industry.

Methods for realizing an enhancement-mode GaN device are mainly divided into three types. A first type of method includes etching away part of AlGaN at a gate to reduce a two-dimensional electron gas concentration of a gate channel, so that the enhancement-mode GaN device is in a closed state without a gate voltage. A second type of method includes implanting a certain number of ions at a gate to deplete a polarized charge of heterojunction and then reduce a density of two-dimensional electron gas at a gate. A third type of method includes laying a layer of P-type gallium nitride on a surface of AlGaN/GaN heterojunction, and using the characteristics of PN junction to exhaust two-dimensional electron gas at a channel, so that a threshold voltage increases from a negative value to about 1 Voltage (V). Among these three methods, the first two methods are difficult to accurately control and mass-produce because of a smaller process window, and then the industry generally uses a P-GaN gate structure.

At present, main bottlenecks of the P-GaN gate structure are as follows. Firstly, a gold semi-contact structure formed by metal and P-GaN cannot withstand a higher voltage, which results in a lower maximum gate voltage (for example, 7 V, while a traditional Si-MOS can withstand a gate voltage of about 20 V) that such GaN devices can withstand. Secondly, a density of two-dimensional electron gas exhausted by a P-N junction is limited, and a threshold voltage is only between 1 V and 2 V (while a threshold voltage of the traditional Si-MOS can be effectively adjusted within 4-10 V). Thirdly, the P-GaN is in direct contact with AlGaN, and an electric field tends to gather in a corner of the P-GaN, thereby resulting in the reduction of a breakdown voltage (BV). As such, multi-layer field plates are needed to disperse the electric field.

### SUMMARY

Objectives of the present disclosure include, for example, providing a power device and a manufacturing method of a power device, which can optimize an electric field distribution at a corner of a gate, improve a breakdown voltage of the power device, optimize a structure of a field plate near the gate, and ensure the performance of the power device.

Embodiments of the present disclosure can be implemented by technical solutions as follows.

In a first aspect, the present disclosure provides a power device, including: a substrate; a compound semiconductor composite layer, disposed on the substrate, where a two-dimensional electron gas is generated in the compound semiconductor composite layer; a P-type gate layer, a source and a drain, which are disposed on the compound semiconductor composite layer; and a gate electrode layer, disposed on the P-type gate layer, where a sidewall of the P-type gate layer facing towards the drain includes a P-type gate slope, and the P-type gate slope is inclined towards the source relative to a surface of the compound semiconductor composite layer.

In a second aspect, the present disclosure provides a power device, including: a substrate; a compound semiconductor composite layer, disposed on the substrate, where a two-dimensional electron gas is generated in the compound semiconductor composite layer; a P-type gate layer, a source and a drain, which are disposed on the compound semiconductor composite layer; and a gate electrode layer, disposed on the P-type gate layer, where the gate electrode layer includes a sidewall facing towards the drain, the sidewall is configured as a gate electrode slope, and the gate electrode slope is inclined towards the source relative to a surface of the P-type gate layer facing away from the compound semiconductor composite layer.

In a third aspect, the present disclosure provides a power device, including: a substrate; a compound semiconductor composite layer, disposed on the substrate, where a two-dimensional electron gas is generated in the compound semiconductor composite layer; a P-type gate layer, disposed on the compound semiconductor composite layer; and a gate electrode layer, disposed on the P-type gate layer, where the P-type gate layer has a first sidewall and a second sidewall, which are opposite in a first direction, and the first sidewall is inclined towards the second sidewall relative to a surface of the compound semiconductor composite layer.

The embodiments of the present disclosure have at least the following beneficial effects.

According to the power device and the manufacturing method thereof provided by the embodiments of the present disclosure, the P-type gate layer, the source and a drain are disposed on the compound semiconductor composite layer, the gate electrode layer is disposed on the P-type gate layer, and a molding structure of the P-type gate layer is defined, i.e., the sidewall of the P-type gate layer facing towards the drain includes the P-type gate slope, and the P-type gate slope is inclined towards the source relative to a surface of the compound semiconductor composite layer, so that through the structure of the P-type gate slope, an edge step of the P-type gate layer can be slowed down and a structure of a field plate prepared near the gate subsequently can be optimized, and problems such as incomplete metal etching of the field plate or metal breakage and voids caused by a step height can be avoided. At the same time, the P-type gate layer can gradually reduce a concentration of the two-dimensional electron gas below the P-type gate layer, increase an on-resistance, and reduce an electric field intensity at the corner of the gate. Compared to existing technologies, the power device and the manufacturing method thereof provided in the embodiments of the present disclosure can optimize the electric field distribution at the corner of the gate, improve a breakdown voltage of the power device, optimize a structure of the field plate near the gate, and ensure the performance of the power device.

### BRIEF DESCRIPTION OF DRAWINGS

In order to explain the technical solutions of the embodiments of the present disclosure more clearly, the following accompanying drawings will be briefly introduced. It should be understood that the following accompanying drawings are merely intended to show some embodiments of the present disclosure, so they should not be regarded as limiting the scope of protection of the present disclosure. For the skilled in the art, other related drawings can be obtained according to these accompanying drawings without creative work.

FIG. 1 illustrates a schematic structural view of a power device according to an embodiment of the present disclosure.

FIG. 2 illustrates a partial schematic structural view of a power device according to an embodiment of the present disclosure.

FIG. 3 illustrates a partial schematic structural view of another power device according to an embodiment of the present disclosure.

FIG. 4 and FIG. 5 illustrate a schematic structural view of still another power device according to an embodiment of the present disclosure.

FIG. 6 through FIG. 10 illustrate process step diagrams of a manufacturing method of a power device according to an embodiment of the present disclosure.

### REFERENCE NUMERALS

100—power device; 110—channel layer; 120—barrier layer; 130—P-type gate layer; 131—P-type gate slope; 132—second inclined surface; 133—first sidewall; 134—second sidewall; 140—source; 150—drain; 160—gate electrode layer; 161—gate electrode slope; 162—first inclined surface; 163—third sidewall; 164—fourth sidewall; 170a—first dielectric layer; 170b—second dielectric layer; 180—first field plate; 190—second field plate; 200—mask layer; L1—spacing; L2—spacing; W1—width; W2—width.

### DETAILED DESCRIPTION OF EMBODIMENTS

As disclosed in the background, in the related art, the main bottlenecks of the P-GaN gate structure are as follows. Firstly, a gold semi-contact structure formed by metal and P-GaN cannot withstand a higher voltage, which results in a lower maximum gate voltage (for example, 7 V, while a traditional Si-MOS can withstand a gate voltage of about 20 V) that such GaN devices can withstand. Secondly, a density of two-dimensional electron gas exhausted by a P-N junction is limited, and a threshold voltage is only between 1 V and 2 V (while a threshold voltage of the traditional Si-MOS can be effectively adjusted within 4-10 V). Thirdly, compared with an insulated gate dielectric, a gate leakage of a P-N junction is larger, and there are some leakage paths on an etched surface and sidewalls of P-GaN. Fourthly, the P-GaN is in direct contact with AlGaN, and an electric field tends to gather in a corner of the P-GaN, thereby resulting in the reduction of a BV. Fifthly, when a field plate is arranged, it is easy to cause the problem of incomplete metal etching of the field plate due to a height of a gate step, or the problem of metal fracture and cavity caused by the gate step.

In order to solve the above problems, the embodiments of the present disclosure provide a power device and a manufacturing method of a power device. It should be noted that features in the embodiments of the present disclosure can be combined with each other without conflict.

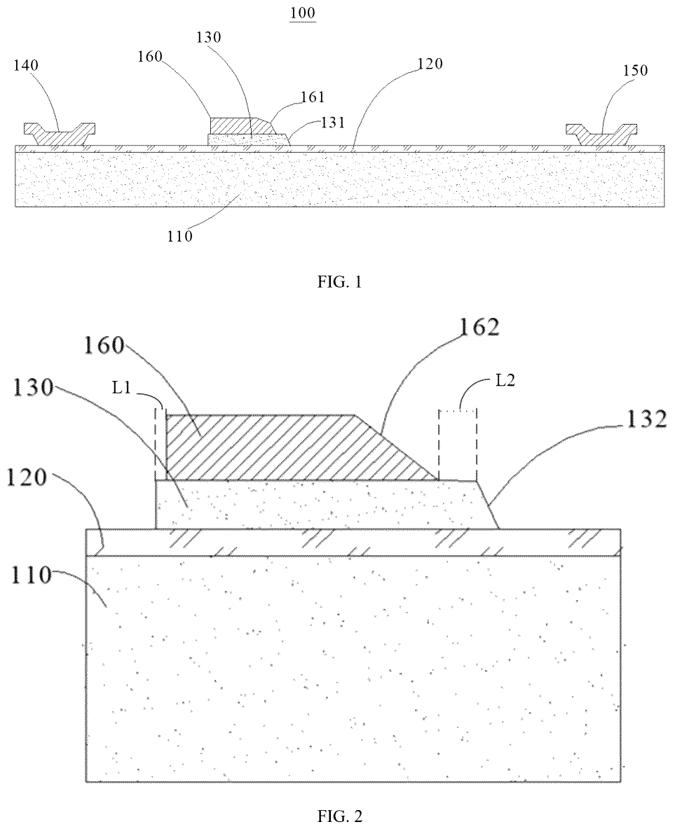

As illustrated in FIG. 1, an embodiment of the present disclosure provides a power device 100, which can optimize an electric field distribution at a corner of a gate, improve a breakdown voltage of the power device, optimize a structure of a field plate near the gate, and ensure the performance of the power device. Further, the power device 100 can also increase a length of a leakage path and reduce a gate leakage.

In an embodiment, the power device 100 includes a compound semiconductor composite layer, a P-type gate layer 130, a source 140, a drain 150, and a gate electrode layer 160. The compound semiconductor composite layer includes a channel layer 110 and a barrier layer 120. The barrier layer 120 is disposed on the channel layer 110. The barrier layer 120 and the channel layer 110 form a heterojunction with a two-dimensional electron gas. The P-type gate layer 130, the source 140 and the drain 150 are all disposed on the barrier layer 120. The gate electrode layer 160 is disposed on the P-type gate layer 130. A sidewall of the P-type gate layer 130 facing towards the drain 150 includes a P-type gate slope 131. The P-type gate slope 131 is inclined towards the source 140 relative to a surface of the barrier layer 120.

In some embodiments, the gate electrode layer 160 includes a sidewall facing towards the drain 150, the sidewall of the gate electrode layer 160 is configured as a gate electrode slope 161, and the gate electrode slope 161 is inclined towards the source 140 relative to a surface of the P-type gate layer 130 facing away from the barrier layer 120.

It should be noted that through the structure of the gate electrode slope 161 and the P-type gate slope 131, an edge step can be slowed down and a structure of a field plate prepared near the gate subsequently can be optimized, and problems such as incomplete metal etching of the field plate or metal breakage and voids caused by a step height can be avoided. Further, the P-type gate layer 130 can gradually reduce a concentration of the two-dimensional electron gas below the P-type gate layer 130, increase an on-resistance, and reduce an electric field intensity at the corner of the gate.

In some embodiments, a width of the P-type gate layer 130 in a first direction is greater than a width of the gate electrode layer 160 in the first direction, and a projection of the gate electrode layer 160 on the barrier layer 120 is within a projection of the P-type gate layer 130 on the barrier layer 120. The first direction is a direction from the source 140 to the drain 150. Specifically, since the width of the P-type gate layer 130 is longer than the width of the gate electrode layer 160, a retraction process of the gate is realized, the gate electrode layer 160 is enabled to be facing away from an etched surface of the P-type gate layer 130, a length of a leakage path on a surface and a sidewall of the power device 100 is increased, and direct contact between the gate electrode layer 160 and a rough sidewall (which is formed after etching) of the P-type gate layer 130 is avoided, thereby reducing the leakage of the drain 150.

In some embodiments, the gate electrode slope 161 includes a first inclined surface 162. The first inclined surface 162 extends from a surface of the P-type gate layer 130 to a top wall of the gate electrode layer 160.

It should also be noted that in this embodiment, a material of the channel layer 110 may be gallium nitride (GaN), a material of the barrier layer 120 may be aluminum gallium nitride (AlGaN), a material of the P-type gate layer 130 may be P-type gallium nitride (p-GaN), a material of the gate electrode layer 160 may be a gate metal, such as titanium nitride (TiN), and a material of each of the source 140 and the drain 150 may be ohmic metal. For materials and basic structures of the above components, the existing enhanced gallium nitride devices can be referred to.

As illustrated in FIG. 2, in some embodiments, the gate electrode slope 161 includes a first inclined surface 162. The first inclined surface 162 extends from a surface of the P-type gate layer 130 to a top wall of the gate electrode layer 160. Specifically, the whole gate electrode slope 161 is inclined, so that the first inclined surface 162 can extend from the P-type gate layer 130 to the top wall of the gate electrode layer 160, thereby realizing a gradient gentle slope structure of the gate electrode slope 161, which is beneficial to the formation of the gate electrode slope 161. In addition, in an actual process, a single inclined surface structure of the gate electrode slope 161 can further avoid the residual accumulation of metal at a step in a gate-drain direction when preparing a field plate.

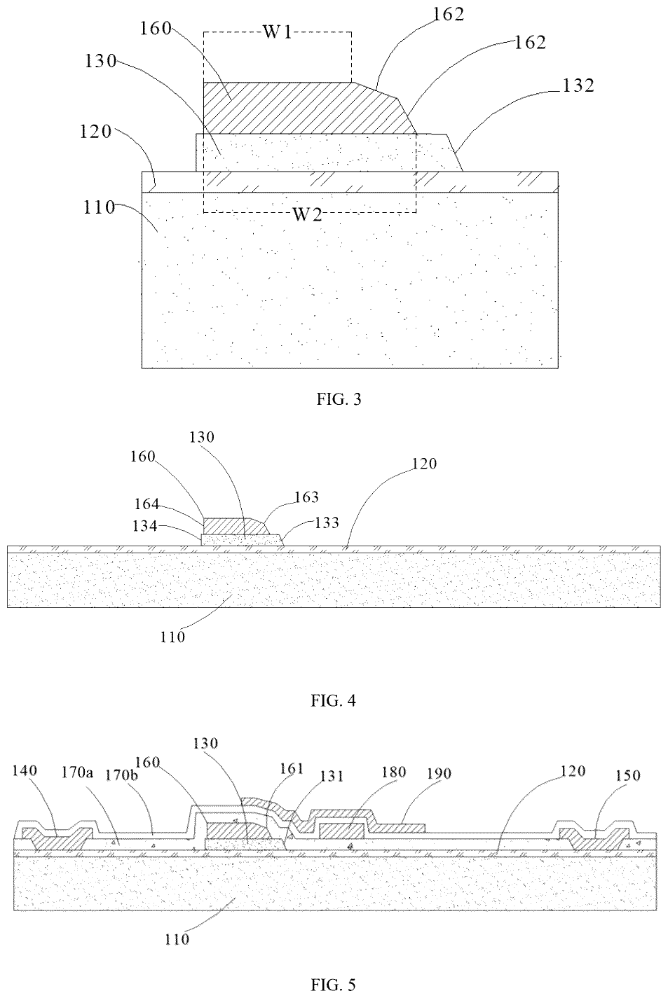

As illustrated in FIG. 3, in some other embodiments, the gate electrode slope 161 includes multiple first inclined surfaces 162. The multiple first inclined surfaces 162 are spliced end-to-end and extend from a surface of the P-type gate layer 130 to a top wall of the gate electrode layer 160. Each of the multiple first inclined surfaces 162 is inclined towards the source 140 relative to a surface of the P-type gate layer 130 facing away from the barrier layer 120. Specifically, the multiple first inclined surfaces 162 are spliced end-to-end in sequence, so that the gate electrode inclined surface 161 presents a polygonal edge structure, which can further slowdown a step gradient of the gate electrode layer 160, further make metal filling for a second field plate 190 more gentle, avoid metal fracture or avoid metal from exposing a space of a medium, and thus ensures the stability of product performance.

In some embodiments, an included angle between the first inclined surface 162 in contact with the P-type gate layer 130 and the surface of the P-type gate layer 130 is in a range from 30° to 85°. Specifically, when the gate electrode slope 161 is composed by a single first inclined surface 162, an included angle between the first inclined surface 162 and the surface of the P-type gate layer 130 is in a range from 30° to 85°, preferably, 60°, which is different from a conventional edge etching slope. When the gate electrode slope 161 is composed by multiple first inclined surfaces 162, an included angle between the first inclined surface 162 of the multiple first inclined surfaces 162 closest to the P-type gate layer 130 and the surface of the P-type gate layer 130 is in a range from 30° to 85°. In the present disclosure, by limiting the included angle, an inclination degree of the gate electrode slope 161 can be limited, and a slope of the step of the gate electrode layer 160 can be slowed down as much as possible on the premise of ensuring the process realization.

In some embodiments, a spacing L1 between a sidewall of the P-type gate layer 130 facing towards the source 140 and a sidewall of the gate electrode layer 160 facing towards the source 140 is greater than or less than a spacing L2 between the sidewall of the P-type gate layer 130 facing towards the drain 150 and the sidewall of the gate electrode layer 160 facing towards the drain 150. Specifically, the gate electrode layer 160 is disposed on the P-type gate layer 130 without exceeding boundaries of the P-type gate layer 130, step surfaces are formed at both sides of the gate electrode layer 160 along the first direction, and widths of the step surfaces are L1 and L2, respectively. In the present disclosure, the widths of the step surfaces at both sides of the gate electrode layer 160 are different, for example, L1 may be greater than L2, which can reduce the metal residue of a first field plate 180 and improve the metal filling of the second field plate 190 more smoothly on the premise of ensuring asymmetry.

In some embodiments, an included angle between the sidewall of the P-type gate layer 130 facing towards the source 140 and the surface of the barrier layer 120 is in a range from 80° to 90°. An included angle between the sidewall of the gate electrode layer 160 facing towards the source 140 and the surface of the P-type gate layer 130 is in a range from 80° to 90°. Specifically, the sidewalls of the P-type gate layer 130 and the gate electrode layer 160 facing towards the source 140 are conventional etching edges, and a single-sided slope structure (i.e., only the sidewall of the P-type gate layer 130 facing towards the drain 150 and the sidewall of the gate electrode layer 160 facing towards the drain 150 have the single-sided slope structure) is adopted in the embodiments of the present disclosure, to reduce the process difficulty and ensure the realizability of the structure, so the structures on both sides of each of the P-type gate layer 130 and the gate electrode layer 160 are asymmetric.

It should be noted that the P-type gate layer 130 will gradually reduce a concentration of the two-dimensional electron gas below the P-type gate layer 130, which will increase an on-resistance value on the one hand and reduce an electric field intensity at a corner of the gate on the other hand. The conventional etching process will form a slope structure with a larger angle on both sides of the P-type gate layer. A slope angle of the conventional P-type gate layer is generally determined by an etching manner, a window of the conventional P-type gate layer is smaller (generally between 80° and 90°), and slopes at both sides of the P-type gate layer are symmetrical. Therefore, if an existing structure is used to adjust an electric field at the corner of the gate, on the one hand, an adjustable window is smaller; on the other hand, there is no higher electric field between the gate and the source, and the symmetrical slopes sacrifice a part of the on-resistance. The structure of the embodiment of the present disclosure can flexibly optimize the above two hands, and the included angle can be transferred to a hard mask through a gradient mask and then transferred to a pattern of the P-type gate layer 130 again, and the inclined angle is in a range from 30° to 85°, and a slope structure for adjusting the electric field only exists between the gate and the drain, thereby avoiding the loss of the on-resistance and the increase of the gate-source distance (Lgs).

In some embodiments, a width W1 of the top wall of the gate electrode layer 160 in the first direction is smaller than a width W2 of a bottom wall of the gate electrode layer 160 in the first direction. Specifically, the gate electrode layer 160 has a structure with the narrower top wall and the wider bottom wall, which can reduce the process difficulty on the one hand and further slowdown a step gradient on the other hand.

In some embodiments, the width W1 of the top wall of the gate electrode layer 160 in the first direction is ½- 9/10 of the width W2 of the bottom wall of the gate electrode layer 160 in the first direction. Specifically, the sidewall of the gate electrode layer 160 facing towards the source 140 is approximately perpendicular to the surface of the P-type gate layer 130, and an included angle between the sidewall of the gate electrode layer 160 facing towards the source 140 and the surface of the P-type gate layer 130 is in a range from 80° to 90°. The gate electrode layer 160 has a structure that is narrower at the top wall and wider at the bottom wall, and the ranges of the widths of the top and bottom walls are limited, which can reduce the process difficulty on the one hand, and can further alleviate the step gradient on the other hand.

Please continue to refer to FIG. 2 or FIG. 3, in some embodiments, the P-type gate slope 131 includes a second inclined surface 132, and an included angle between the second inclined surface 132 and the surface of the barrier layer 120 is in a range from 30° to 90°. Specifically, the P-type gate slope 131 has a single slope structure, that is to say, the P-type gate slope 131 is composed by the single second inclined surface 132, and a slope angle of the P-type gate slope 131 with respect to the barrier layer 120 is also be determined by etching conditions. In a specific embodiment, the included angle of the second inclined surface 132 with respect to the surface of the barrier layer 120 is 60°, so as to reduce the concentration of the two-dimensional electron gas below the P-type gate layer 130 in a gradient manner in a wider range as much as possible.

Please continue to refer to FIG. 1 through FIG. 3, an embodiment of the present disclosure also provides a power device 100, which includes a compound semiconductor composite layer, a P-type gate layer 130, a source 140, a drain 150, and a gate electrode layer 160. The compound semiconductor composite layer includes a channel layer 110 and a barrier layer 120. The barrier layer 120 is disposed on the channel layer 110. The barrier layer 120 and the channel layer 110 form a heterojunction with a two-dimensional electron gas. The P-type gate layer 130 is disposed on the barrier layer 120. The gate electrode layer 160 is disposed on the P-type gate layer 130. The gate electrode layer 160 includes a sidewall facing towards the drain 150, the sidewall is configured as a gate electrode slope 161, and the gate electrode slope 161 is inclined towards the source 140 relative to a surface of the P-type gate layer 130 facing away from the compound semiconductor composite layer.

In some embodiments, a sidewall of the P-type gate layer 130 facing towards the drain 150 includes a P-type gate slope 131, and the P-type gate slope 131 is inclined towards the source 140 relative to a surface of the barrier layer 120.

As illustrated in FIG. 4, an embodiment of the present disclosure also provides a power device 100, which includes a compound semiconductor composite layer, a P-type gate layer 130, a source 140, a drain 150, and a gate electrode layer 160. The compound semiconductor composite layer includes a channel layer 110 and a barrier layer 120. The barrier layer 120 is disposed on the channel layer 110. The barrier layer 120 and the channel layer 110 form a heterojunction with a two-dimensional electron gas. The P-type gate layer 130 is disposed on the barrier layer 120. The gate electrode layer 160 is disposed on the P-type gate layer 130. The gate electrode layer 160 has a third sidewall 163 and a fourth sidewall 164 along the first direction, and the third sidewall 163 is inclined towards the fourth sidewall 164 relative to a surface of the P-type gate layer 130. The P-type gate layer 130 has a first sidewall 133 and a second sidewall 134 along the first direction. The first sidewall 133 and the third sidewall 163 are arranged adjacent to each other at a same side, and the first sidewall 133 is inclined towards the second sidewall 134 relative to a surface of the barrier layer 120. Specifically, the third sidewall 163 and the first sidewall 133 are both arranged in a direction close to the drain electrode 150, and the fourth sidewall 164 and the second sidewall 134 are both arranged in a direction close to the source electrode 140, which can also achieve the aforementioned technical effects of the power device 100.

Referring to FIG. 5, an embodiment of the present disclosure also provides a power device 100, which includes a compound semiconductor composite layer, a P-type gate layer 130, a source 140, a drain 150, and a gate electrode layer 160. The compound semiconductor composite layer includes a channel layer 110 and a barrier layer 120. The barrier layer 120 is disposed on the channel layer 110. The barrier layer 120 and the channel layer 110 form a heterojunction with a two-dimensional electron gas. The P P-type gate layer 130 is disposed on the barrier layer 120. The gate electrode layer 160 is disposed on the P-type gate layer 130. A sidewall of the gate electrode layer 160 facing towards the drain 150 includes a gate electrode slope 161. The gate electrode slope 161 is inclined towards the source 140 relative to a surface of the P-type gate layer 130. A sidewall of the P-type gate layer 130 facing towards the drain 150 includes a P-type gate slope 131. The P-type gate slope is inclined towards the source 140 relative to a surface of the P-type gate layer 130 facing away from the compound semiconductor composite layer.

In some embodiments, the power device 100 further includes a first dielectric layer 170a, a first field plate 180, a second dielectric layer 170b, and a second field plate 190. The first dielectric layer 170a is disposed on the barrier layer 120 and covers the gate electrode layer 160. The first field plate 180 is disposed on the first dielectric layer 170a. The second dielectric layer 170b is disposed on the first dielectric layer 170a and covers the first field plate 180. The second field plate 190 is disposed on the second dielectric layer 170b. The first field plate 180 and the second field plate 190 are both disposed between the P-type gate layer 130 and the drain 150. A sidewall of the gate electrode layer 160 facing towards the drain 150 includes a gate electrode slope 161. The gate electrode slope 161 is inclined towards the source 140 relative to a surface of the P-type gate layer 130. A sidewall of the P-type gate layer 130 facing towards the drain 150 includes a P-type gate slope 131. The P-type gate slope is inclined towards the source 140 relative to a surface of the P-type gate layer 130 facing away from the compound semiconductor composite layer. A projection of the second field plate 190 on the barrier layer 120 overlaps with each of a projection of the gate electrode slope 161 on the barrier layer 120 and a projection of the P-type gate slope 131 on the barrier layer 120.

It should be noted that, in some embodiments, the barrier layer 120 is provided with the first dielectric layer 170a, and the first dielectric layer 170a covers the gate electrode layer 160 and is provided with the first field plate 180 thereon. In addition, the second dielectric layer 170b is disposed on the first dielectric layer 170a and covers the first field plate 180, and the second field plate 190 is disposed on the second dielectric layer 170b. Moreover, The first field plate 180 and the second field plate 190 are both disposed between the P-type gate layer 130 and the drain 150, and the projection of the second field plate 190 on the barrier layer 120 overlaps with each of the projection of the gate electrode slope 161 on the barrier layer 120 and the projection of the P-type gate slope 131 on the barrier layer 120. In a conventional process, due to thinner thicknesses of a field plate metal and a dielectric below the field plate metal, in an etching process, the field plate metal is often etched incompletely due to a larger step gradient, that is, irregular residual metal will be formed on both sides of a corresponding step when the first field plate 180 is formed by using the conventional technology. When this kind of irregular residual metal is between the gate and drain, it will cause an electric field to gather at a sharp part of the irregular residual metal at any time, thereby breaking down the power device in advance and affecting the performance of the power device. However, the structures of the gate electrode slope 161 and the P-type gate slope 131 in the embodiments of the present disclosure can effectively alleviate the accumulation of the irregular residual metal at the step in a gate-drain direction. In addition, the sloping structure is also beneficial to form a morphology of the second field plate 190, which further makes metal filling for the second field plate 190 more gentle, and avoids metal fracture or avoid metal from exposing a space of a medium, and thus ensures the stability of product performance.

An embodiment of the present disclosure also provides a manufacturing method of a power device, which is used for preparing the power device 100 described above.

In some embodiments, the manufacturing method includes the following steps:
forming the compound semiconductor composite layer on the substrate;
forming the P-type gate layer 130 on the compound semiconductor composite layer;
forming the gate electrode layer 160 on the P-type gate layer 130; and
performing an etching process on the gate electrode layer 160 and the P-type gate layer 130 to remove a part of the gate electrode layer 160 and a part of the P-type gate layer 130 to thereby obtain the power device 100, where the sidewall of the P-type gate layer 130 facing towards a drain 150 includes the P-type gate slope 131, and the P-type gate slope 131 is inclined towards the source 140 relative to the surface of the barrier layer 120.

In some embodiments, the manufacturing method includes the following steps:
forming the compound semiconductor composite layer on the substrate;
forming the P-type gate layer 130 on the compound semiconductor composite layer;
forming the gate electrode layer 160 on the P-type gate layer 130; and
performing an etching process on the gate electrode layer 160 and the P-type gate layer 130 to remove a part of the gate electrode layer 160 and a part of the P-type gate layer 130 to thereby obtain the power device 100, where the sidewall of the gate electrode layer 160 facing towards the drain 150 includes the gate electrode slope 161, and the gate electrode slope 161 is inclined towards the source 140 relative to the surface of the P-type gate layer 130 facing away from the barrier layer 120.

In some embodiments, the manufacturing method includes the following steps:
forming the compound semiconductor composite layer on the substrate;
forming the P-type gate layer 130 on the compound semiconductor composite layer;
forming the gate electrode layer 160 on the P-type gate layer 130; and
performing an etching process on the gate electrode layer 160 and the P-type gate layer 130 to remove a part of the gate electrode layer 160 and a part of the P-type gate layer 130 to thereby obtain the power device 100, where the sidewall of the gate electrode layer 160 facing towards the drain 150 includes the gate electrode slope 161, the gate electrode slope 161 is inclined towards the source 140 relative to the surface of the P-type gate layer 130 facing away from the barrier layer 120, the sidewall of the P-type gate layer 130 facing towards the drain 150 includes the P-type gate slope 131, the P-type gate slope 131 is inclined towards the source 140 relative to the surface of the barrier layer 120.

Specifically, the compound semiconductor composite layer includes a channel layer and a barrier layer, and in an actual preparation, the manufacturing method may include the following steps.

In a first step, the barrier layer 120 is formed on the channel layer 110. In a specific embodiment, an AlGaN layer (i.e., the barrier layer 120) is deposited and formed on a GaN layer (i.e., the channel layer 110) by using a conventional epitaxial growth technology.

In a second step, the P-type gate layer 130 is formed on the barrier layer 120. In a specific embodiment, after the AlGaN layer is formed, a P-GaN layer can be deposited on the AlGaN layer by the deposition process again, to thereby form the P-type gate layer 130.

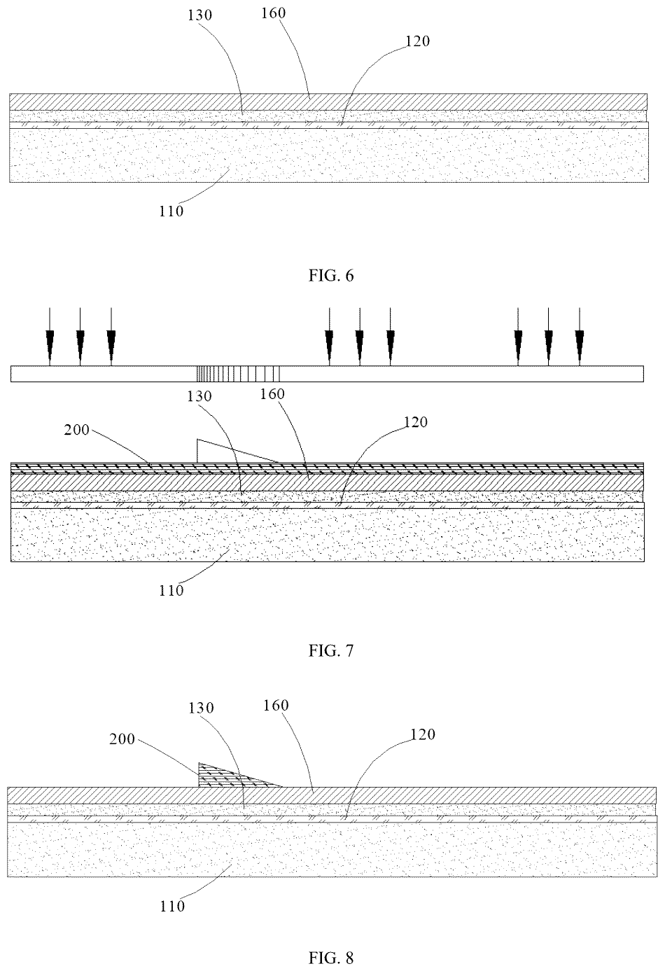

In a third step, the gate electrode layer 160 is formed on the P-type gate layer 130. In a specific embodiment, referring to FIG. 6, after the P-GaN layer is formed, a layer of gate metal, such as TiN, may be deposited on the P-GaN layer by using the deposition process again, thereby to form the gate electrode layer 160. The first, second, and third steps are consistent with the conventional steps.

In a fourth step, an etching process is performed on the gate electrode layer 160 and the P-type gate layer 130 to remove a part of the gate electrode layer 160 and a part of the P-type gate layer 130.

Specifically, referring to FIGS. 7 to 10, the fourth step is used to etch the gate electrode layer 160 and the P-type gate layer 130, thereby forming the gate electrode layer 160 and the P-type gate layer 130 with special features according to the embodiments of the present disclosure. In an actual etching, firstly, a mask layer 200 is formed on the gate electrode layer 160, then a photoresist layer is formed on the mask layer 200, and then a part of the photoresist layer is etched by a gradient gray mask to form a mask pattern. Subsequently, the mask pattern is transferred to the mask layer 200 by dry etching, then a part of the gate electrode layer 160 and a part of the P-type gate layer 130 are removed by dry etching, a part of the mask layer 200 and a part of the gate electrode layer 160 are removed by wet etching, and finally, the rest of the mask layer 200 is removed. The mask layer 200 may be silicon dioxide (SiO₂).

Referring to FIG. 7, in an actual etching, a hard mask can be deposited first, and a preliminary morphology can be transferred to the photoresist with a gradient gray mask, which is realized by electron beam gray lithography (or laser direct writing). Further, a lithography energy in a non-patterned area may be defined to be 100%, an energy on a left side of a grid diagram is 0, an energy on a right side of the grid diagram is 80%, and an energy in the middle of the grid diagram is changed with a gradient of 1%-10%. When the gradient is smaller, a slope of the formed photoresist is smoother; if the gradient is larger, a surface of the formed photoresist is also slightly stepped, and the specific energy value can be defined in combination with the photoresist type.

Referring to FIG. 8, the desired topography is then transferred to the hard mask by dry etching. That is, the conventional etching process is used for dry etching, and a selection ratio of the photoresist to the hard mask is in a range from 1:10 to 1:1.

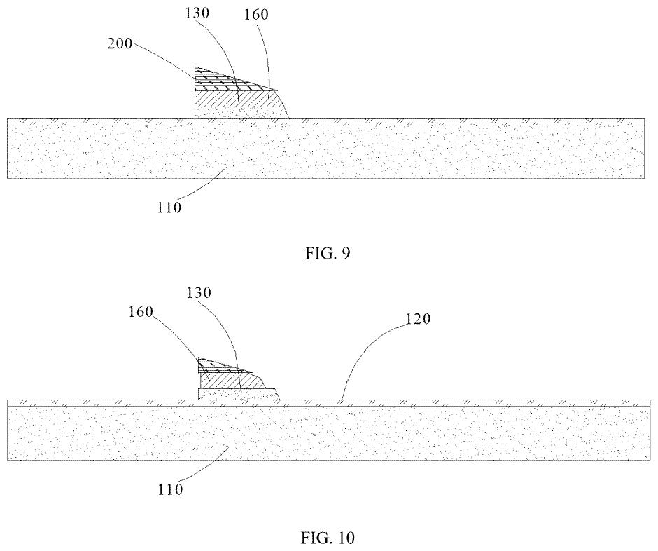

Referring to FIG. 9, the corresponding gate morphology is etched by dry etching again. Two layers of TiN and P-GaN are etched by using the same photomask, in which a selection ratio of the hard mask to TiN is relatively larger, which is in a range from 1:20 to 1:5, and an idle ratio of the hard mask and the P-GaN is in a range from 1:10 to 1:1. After this step, the basic shapes of the gate electrode layer 160 and the P-type gate layer 130 can be formed.

Referring to FIG. 10, the gate electrode layer 160 and the hard mask are further etched, and the morphology of the hard mask and the gate metal is adjusted by adjusting the etching selectivity. Specifically, wet etching can be selected, and the combing for etching TiN and SiO₂ is close, and the selection ratio is close to 1:1, and P-GaN will not be etched in this step.

Finally, the hard mask is removed, and the formed P-type gate layer 130 and gate electrode layer 160 form a special morphology, and then the source 140, drain 150 and other structures are prepared. Specifically, the sidewall of the gate electrode layer 160 facing towards the drain 150 includes the gate electrode slope 161, which is inclined towards the source 140 relative to the surface of the P-type gate layer 130 facing away from the barrier layer 120, and the sidewall of the P-type gate layer 130 facing towards the drain 150 includes the P-type gate slope 131, which is inclined towards the source 140 relative to the surface of the barrier layer 120.

In summary, in the power device 100 and its manufacturing method provided by the embodiments of the present disclosure, the barrier layer 120 is disposed on the channel layer 110, so that the barrier layer 120 and the channel layer 110 form a heterojunction with a two-dimensional electron gas, the P-type gate layer 130, the source 140 and the drain 150 are disposed on the barrier layer 120, and finally the gate electrode layer 160 is disposed on the P-type gate layer 130. The molding structures of the P-type gate layer 130 and the gate electrode layer 160 are defined, i.e., the sidewall of the gate electrode layer 160 facing towards the drain 150 includes the gate electrode slope 161, which is inclined relative to the P-type gate layer 130, and the sidewall of the P-type gate layer 130 facing towards the drain 150 includes the P-type gate slope 131, which is inclined relative to the barrier layer 120. Through the structure of the gate electrode slope 161 and the P-type gate slope 131, the edge step can be slowed down, a structure of a field plate prepared near the gate subsequently can be optimized, and problems such as incomplete metal etching of the field plate or metal breakage and voids caused by a step height can be avoided. At the same time, the P-type gate layer 130 can gradually reduce a concentration of the two-dimensional electron gas below the P-type gate layer, increase an on-resistance, and reduce an electric field intensity at the corner of the gate. Compared to existing technologies, the power device 100 and the manufacturing method thereof provided in the embodiments of the present disclosure can optimize the electric field distribution at the corner of the gate, improve a breakdown voltage of the power device, optimize a structure of the field plate near the gate, and ensure the performance of the power device. In addition, the gate electrode layer 160 is disposed to be face away from an etched surface of the P-type gate layer 130, a length of a leakage path on a surface and a sidewall of the power device 100 is increased, and direct contact between the gate electrode layer 160 and a rough sidewall (which is formed after etching) of the P-type gate layer 130 is avoided, thereby reducing the leakage of the drain 150

The above embodiments are only specific embodiments of the present disclosure, but the scope of protection of the present disclosure is not limited thereto. Any change or substitution that can be easily thought of by a person familiar with the technical field within the technical scope disclosed by the present disclosure should be covered by the scope of protection of the present disclosure. Therefore, the scope of protection of the present disclosure should be based on the scope of protection of the claims.

What is claimed is:

1. A power device, comprising:
a substrate;
a compound semiconductor composite layer, disposed on the substrate, wherein a two-dimensional electron gas is generated in the compound semiconductor composite layer;
a P-type gate layer (130), a source (140) and a drain (150), disposed on the compound semiconductor composite layer; and
a gate electrode layer (160), disposed on the P-type gate layer (130),
wherein a sidewall of the P-type gate layer (130) facing towards the drain (150) comprises a P-type gate slope (131), and the P-type gate slope (131) is inclined towards the source (140) relative to a surface of the compound semiconductor composite layer.

2. The power device as claimed in claim 1, wherein the gate electrode layer (160) comprises a sidewall facing towards the drain (150), the sidewall of the gate electrode layer (160) is configured as a gate electrode slope (161), and the gate electrode slope (161) is inclined towards the source (140) relative to a surface of the P-type gate layer (130) facing away from the compound semiconductor composite layer.

3. The power device as claimed in claim 2, wherein a width of the P-type gate layer (130) in a first direction is greater than a width of the gate electrode layer (160) in the first direction, a projection of the gate electrode layer (160) on the compound semiconductor composite layer is within a projection of the P-type gate layer (130) on the compound semiconductor composite layer, and the first direction is a direction from the source (140) to the drain (150).

4. The power device as claimed in claim 3, wherein the gate electrode slope (161) comprises a first inclined surface (162), and the first inclined surface (162) extends from the surface of the P-type gate layer (130) to a top wall of the gate electrode layer (160).

5. The power device as claimed in claim 3, wherein the gate electrode slope (161) comprises a plurality of first inclined surfaces (162), the plurality of first inclined surfaces (162) are spliced end-to-end and extend from the surface of the P-type gate layer (130) to a top wall of the gate electrode layer (160), and each of the plurality of first inclined surfaces (162) is inclined towards the source (140) relative to the surface of the P-type gate layer (130) facing away from the compound semiconductor composite layer.

6. The power device as claimed in claim 5, wherein an included angle between the first inclined surface (162) in contact with the P-type gate layer (130) of the plurality of first inclined surfaces (162) and the surface of the P-type gate layer (130) is in a range from 30° to 85°.

7. The power device as claimed in claim 3, wherein a spacing (L1) in the first direction between a sidewall of the P-type gate layer (130) facing towards the source (140) and a sidewall of the gate electrode layer (160) facing towards the source (140) is less than a spacing (L2) in the first direction between the sidewall of the P-type gate layer (130) facing towards the drain (150) and the sidewall of the gate electrode layer (160) facing towards the drain (150).

8. The power device as claimed in claim 3, wherein an included angle between a sidewall of the P-type gate layer (130) facing towards the source (140) and the surface of the compound semiconductor composite layer is in a range from 80° to 90°, and an included angle between a sidewall of the gate electrode layer (160) facing towards the source (140) and a surface of the P-type gate layer (130) is in a range from 80° to 90°.

9. The power device as claimed in claim 3, wherein a width (W1) of a top wall of the gate electrode layer (160) in the first direction is smaller than a width (W2) of a bottom wall of the gate electrode layer (160) in the first direction.

10. The power device as claimed in claim 9, wherein the width (W1) of the top wall of the gate electrode layer (160) in the first direction is ½- 9/10 of the width (W2) of the bottom wall of the gate electrode layer (160) in the first direction.

11. The power device as claimed in claim 2, wherein the P-type gate slope (131) comprises a second inclined surface (132), and an included angle of the second inclined surface (132) and the surface of the compound semiconductor composite layer is in a range from 30° to 90°.

12. A power device, comprising:
a substrate;
a compound semiconductor composite layer, disposed on the substrate, wherein a two-dimensional electron gas is generated in the compound semiconductor composite layer;
a P-type gate layer (130), a source (140) and a drain (150), disposed on the compound semiconductor composite layer; and
a gate electrode layer (160), disposed on the P-type gate layer (130);
wherein the gate electrode layer (160) comprises a sidewall facing towards the drain (150), the sidewall of the gate electrode layer (160) is configured as a gate electrode slope (161), and the gate electrode slope (161) is inclined towards the source (140) relative to a surface of the P-type gate layer (130) facing away from the compound semiconductor composite layer.

13. The power device as claimed in claim 12, wherein a sidewall of the P-type gate layer (130) facing towards the drain (150) comprises a P-type gate slope (131), and an included angle between the P-type gate slope (131) and the surface of the P-type gate layer (130) is in a range from 30° to 90°.

14. The power device as claimed in claim 13, wherein the gate electrode slope (161) comprises a plurality of first inclined surfaces (162), the plurality of first inclined surfaces (162) are spliced end-to-end and extend from the surface of the P-type gate layer (130) to a top wall of the gate electrode layer (160), each of the plurality of first inclined surfaces (162) is inclined towards the source (140) relative to the surface of the P-type gate layer (130) facing away from the compound semiconductor composite layer, and an included angle between the first inclined surface (162) in contact with the P-type gate layer (130) of the plurality of first inclined surfaces (162) and the surface of the P-type gate layer (130) is in a range from 30° to 85°; and
wherein the P-type gate slope (131) comprises a second inclined surface (132), and an included angle of the second inclined surface (132) and a surface of the compound semiconductor composite layer is in a range from 30° to 90°.

15. The power device as claimed in claim 12, wherein a spacing (L1) in a first direction between a sidewall of the P-type gate layer (130) facing towards the source (140) and a sidewall of the gate electrode layer (160) facing towards the source (140) is less than a spacing (L2) in the first direction between a sidewall of the P-type gate layer (130) facing towards the drain (150) and the sidewall of the gate electrode layer (160) facing towards the drain (150).

16. The power device as claimed in claim 12, wherein an included angle between a sidewall of the P-type gate layer (130) facing towards the source (140) and a surface of the compound semiconductor composite layer is in a range from 80° to 90°, and an included angle between a sidewall of the gate electrode layer (160) facing towards the source (140) and the surface of the P-type gate layer (130) is in a range from 80° to 90°.

17. The power device as claimed in claim 12, wherein a width (W1) of a top wall of the gate electrode layer (160) in a first direction is smaller than a width (W2) of a bottom wall of the gate electrode layer (160) in the first direction.

18. The power device as claimed in claim 17, wherein the width (W1) of the top wall of the gate electrode layer (160) in the first direction is ½- 9/10 of the width (W2) of the bottom wall of the gate electrode layer (160) in the first direction.

19. A power device, comprising:
a substrate;
a compound semiconductor composite layer, disposed on the substrate, wherein a two-dimensional electron gas is generated in the compound semiconductor composite layer;
a P-type gate layer (130), disposed on the compound semiconductor composite layer; and
a gate electrode layer (160), disposed on the P-type gate layer (130);
wherein the P-type gate layer (130) has a first sidewall (133) and a second sidewall (134) which are opposite in a first direction, and the first sidewall (133) is inclined towards the second sidewall (134) relative to a surface of the compound semiconductor composite layer.

20. The power device as claimed in claim 19, further comprising:
a source (140) and a drain (150), disposed on the compound semiconductor composite layer;
a first dielectric layer (170a), disposed on the compound semiconductor composite layer and covering the gate electrode layer (160);
a first field plate (180), disposed on the first dielectric layer (170a);
a second dielectric layer (170b), disposed on the first dielectric layer (170a) and covering the first field plate (180); and
a second field plate (190), disposed on the second dielectric layer (170b);
wherein the gate electrode layer (160) comprises a sidewall facing towards the drain (150), the sidewall of the gate electrode layer (160) is configured as a gate electrode slope (161), and the gate electrode slope (161) is inclined towards the source (140) relative to a surface of the P-type gate layer (130) facing away from the compound semiconductor composite layer;
wherein a sidewall of the P-type gate layer (130) facing towards the drain (150) comprises a P-type gate slope (131); and
wherein the first field plate (180) and the second field plate (190) are both disposed between the P-type gate layer (130) and the drain (150), and a projection of the second field plate (190) on the compound semiconductor composite layer overlaps with each of a projection of the gate electrode slope (161) on the compound semiconductor composite layer and a projection of the P-type gate slope (131) on the compound semiconductor composite layer.
